(19) United States
(12) Patent Application Publication
(10) Pub. No.: US 2018/0332686 A1
(43) Pub. Date: Nov. 15, 2018

(54) COMPOSITION, CURED PRODUCT AND SEMICONDUCTOR LIGHT EMITTING DEVICE

(71) Applicant: Sumitomo Chemical Company, Limited, Tokyo (JP)

(72) Inventors: Shohei HOTTA, Osaka (JP); Masayuki TAKASHIMA, Osaka (JP)

(21) Appl. No.: 15/595,096

(22) Filed: May 15, 2017

(51) Int. Cl. H05B 33/14; C09K 11/08; C09K 11/65; C08K 3/08; C08K 3/34; C09K 11/59; C09K 11/64; H01L 33/56

(52) U.S. Cl. CPC H05B 33/14; C09K 11/08; C09K 11/655; C08K 3/08; C08K 2003/0812; C09K 11/59; C09K 11/64; H01L 33/56; C08K 3/34

(57) ABSTRACT

A composition is provided which is useful for the production of a cured product which is excellent in heat resistance and light permeability. The composition includes a polysiloxane, at least one alkoxysilane partial condensate having no hydroxyl group selected from the group consisting of a T-type alkoxysilane partial condensate having no hydroxyl group and a Q-type alkoxysilane partial condensate having no hydroxyl group, and a phosphoric acid-based catalyst. The polysiloxane is represented by the following formula (1):

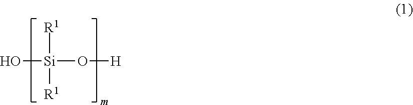

In formula (1), m represents an integer of 5 to 3000 and R¹ represents an alkyl group. The plurality of R¹ may be the same or different.

### TECHNICAL FIELD

The present invention relates to a composition, a cured product of the composition and a semiconductor light emitting device comprising the cured product.

### BACKGROUND ART

Patent document 1 discloses a composition obtained by dealcoholizing a mixture comprising a polysiloxane having a silanol group at each of both terminal ends and a tetraalkoxysilane partial condensate, using an organometallic catalyst, as an encapsulating material composition used for production of a semiconductor light emitting device.

### PRIOR ART DOCUMENT

### Patent Document

Patent document 1: International Publication WO2010/090280

However, a cured product obtained by curing the above-described encapsulating material composition is not always sufficient in heat resistance and light permeability.

### SUMMARY OF THE INVENTION

### Problem to be Solved by the Invention

Then, the present invention has an object of providing a composition which is useful for production of a cured product excellent in heat resistance and light permeability, a cured product of the composition and a semiconductor light emitting device comprising the cured product.

### Means for Solving the Problem

The present invention provides the following [1] to [8].

[1] A composition comprising

a polysiloxane represented by the formula (1),

at least one alkoxysilane partial condensate having no hydroxyl group selected from the group consisting of a T-type alkoxysilane partial condensate having no hydroxyl group and a Q-type alkoxysilane partial condensate having no hydroxyl group, and

a phosphoric acid-based catalyst:

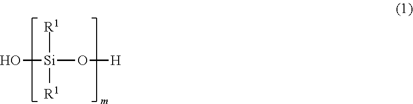

(wherein, m represents an integer of 5 to 3000. R¹ represents an alkyl group. The plurality of R¹ may be the same or different.).

[2] The composition according to [1], wherein the T-type alkoxysilane partial condensate having no hydroxyl group is an alkoxysilane partial condensate having a partial structure represented by the formula (2):

R²—Si(O—)ₙ(OR³)₃₋ₙ (2)

(wherein, n represents an integer of 1 to 3. R² represents an alkyl group. R³ represents a methyl group or an ethyl group. When a plurality of R³ are present, they may be the same or different.).

[3] The composition according to [1], wherein the Q-type alkoxysilane partial condensate having no hydroxyl group is an alkoxysilane partial condensate having a partial structure represented by the formula (3):

Si(O—)ₘ(OR⁴)₄₋ₘ (3)

(wherein, m represents an integer of 1 to 4. R⁴ represents a methyl group or an ethyl group. When a plurality of R⁴ are present, they may be the same or different.).

[4] The composition according to [1], wherein the blending amount of the at least one alkoxysilane partial condensate having no hydroxyl group selected from the group consisting of the T-type alkoxysilane partial condensate having no hydroxyl group and the Q-type alkoxysilane partial condensate having no hydroxyl group is 1 to 15 parts by weight with respect to 100 parts by weight of the polysiloxane.

[5] The composition according to [1], wherein the standard polystyrene-equivalent weight-average molecular weight of the polysiloxane represented by the formula (1) is 5000 to 200000.

[6] A cured product obtained by curing the composition according to [1].

[7] A semiconductor light emitting device comprising a semiconductor light emitting element and an encapsulating layer comprising the cured product according to [6].

[8] The semiconductor light emitting device according to [7], wherein the semiconductor light emitting element is a UV-LED device.

### Effect of the Invention

According to the present invention, a composition which is useful for production of a cured product excellent in heat resistance and light permeability, a cured product of the composition and a semiconductor light emitting device comprising the cured product can be provided.

### MODES FOR CARRYING OUT THE INVENTION

The composition of the present invention is a composition comprising a polysiloxane represented by the formula (1), at least one alkoxysilane partial condensate having no hydroxyl group selected from the group consisting of a T-type alkoxysilane partial condensate having no hydroxyl group and a Q-type alkoxysilane partial condensate having no hydroxyl group, and a phosphoric acid-based catalyst.

### [Polysiloxane Represented by the Formula (1)]

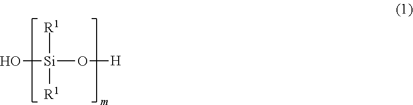

(wherein, m represents an integer of 5 to 3000. R¹ represents an alkyl group. The plurality of R¹ may be the same or different.).

R¹ is preferably an alkyl group having 1 to 20 carbon atoms, more preferably an alkyl group having 1 to 10 carbon atoms, further preferably a methyl group. When R¹ is a methyl group, the polysiloxane represented by the formula (1) is a silicone oil.

The composition of the present embodiment may comprise one polysiloxane represented by the formula (1) singly or may comprise two or more polysiloxanes represented by the formula (1).

The standard polystyrene-equivalent weight-average molecular weight of the polysiloxane represented by the formula (1) is usually 500 to 300000, preferably 2000 to 200000, more preferably 5000 to 200000. The standard polystyrene-equivalent weight-average molecular weight is usually measured by gel permeation chromatography (GPC).

### [Alkoxysilane Partial Condensate Having No Hydroxyl Group]

The composition of the present embodiment may comprise only a T-type alkoxysilane partial condensate having no hydroxyl group, may comprise only a Q-type alkoxysilane partial condensate having no hydroxyl group, or may comprise both a T-type alkoxysilane partial condensate having no hydroxyl group and a Q-type alkoxysilane partial condensate having no hydroxyl group, as the alkoxysilane partial condensate having no hydroxyl group.

The T-type denotes a siloxane structure having a RSiO_{3/2} unit (wherein R represents a monovalent organic group). The Q-type denotes a siloxane structure having a SiO_{4/2} unit.

The T-type alkoxysilane partial condensate having no hydroxyl group is preferably an alkoxysilane partial condensate having a partial structure represented by the formula (2).

R²—Si(O—)ₙ(OR³)₃₋ₙ (2)

(wherein, n represents an integer of 1 to 3. R² represents an alkyl group. R³ represents a methyl group or an ethyl group. When a plurality of R³ are present, they may be the same or different.).

R² is preferably an alkyl group having 1 to 20 carbon atoms, more preferably an alkyl group having 1 to 10 carbon atoms, further preferably a methyl group.

R³ is preferably a methyl group.

The specific partial structure represented by the formula (2) includes a partial structure represented by the formula (2-1) (hereinafter, referred to also as “T1 partial structure”), a partial structure represented by the formula (2-2) (hereinafter, referred to also as “T2 partial structure”) and a partial structure represented by the formula (2-3) (hereinafter, referred to also as “T3 partial structure”.

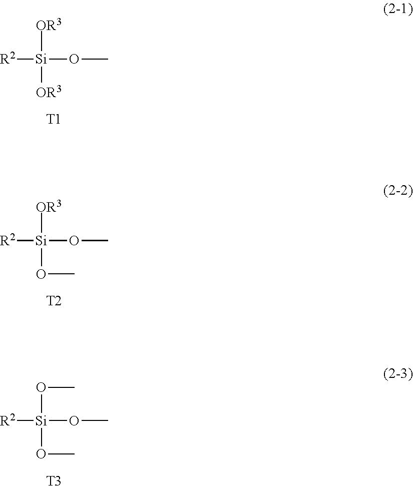

(wherein, R² and R³ represent the same meaning as described above).

The alkoxysilane partial condensate having a partial structure represented by the formula (2) is preferably constituted of “T1 partial structure”, “T2 partial structure” and “T3 partial structure” at optional combination and ratio. The whole structure of the alkoxysilane partial condensate having a partial structure represented by the formula (2) may be any of straight chain, cycle, ladder, basket and random morphology.

When volatility of the alkoxysilane partial condensate having a partial structure represented by the formula (2) is low, control of the mixing ratio is easy in mixing the polysiloxane represented by the formula (1) and the alkoxysilane partial condensate having a partial structure represented by the formula (2), and a desired cured product is obtained easily in curing the composition of the present embodiment. From these standpoints, it is preferable that the alkoxysilane partial condensate having a partial structure represented by the formula (2) is a liquid material. The viscosity at 25° C. of the liquid material is usually 4 to 500 mPa·s, preferably 4 to 300 mPa·s, more preferably 4 to 100 mPa·s. When the lower limit of the viscosity of the liquid material is within these ranges, the volatility of the alkoxysilane partial condensate having a partial structure represented by the formula (2) tends to lower. When the upper limit of the viscosity of the liquid material is within these ranges, it becomes easy to mix with the polysiloxane represented by the formula (1) uniformly. The viscosity of the liquid material can be measured, for example, by a B-type rotational viscometer.

The alkoxysilane partial condensate having a partial structure represented by the formula (2) includes, for example, a condensate obtained by adding water to a hydrolyzable trialkoxysilane, then, condensing the silane via a dehydration reaction of an alkoxy group and a hydroxyl group and a dealcoholization reaction, by addition of a catalyst and/or heating.

The hydrolyzable trialkoxysilane includes, for example, methyltrimethoxysilane, methyltriethoxysilane, ethyltrimethoxysilane, ethyltriethoxysilane and methylisopropoxysilane. Of them, methyltrimethoxysilane or methyltriethoxysilane is preferable, from the standpoint of stability of the viscosity of the composition of the present embodiment and easiness of curing of the composition.

Specific examples of the T-type alkoxysilane partial condensate having no hydroxyl group include SS-101 manufactured by COLCOAT Co., Ltd., methyltrimethoxysilane condensate (MTMS-A) manufactured by Tama Chemicals Co., Ltd., KC-89S, KR-500 and X-40-9225 manufactured by Shin-Etsu Chemical Co., Ltd., SR2402 manufactured by Dow Corning Toray Co., Ltd. and SILRES MES 100 manufactured by Wacker Asahikasei Silicone Co., Ltd.

The Q-type alkoxysilane partial condensate having no hydroxyl group is preferably an alkoxysilane partial condensate having a partial structure represented by the formula (3):

Si(O—)ₘ(OR⁴)₄₋ₘ (3)

(wherein, m represents an integer of 1 to 4. R⁴ represents a methyl group or an ethyl group. When a plurality of R⁴ are present, they may be the same or different.).

The specific partial structure represented by the formula (3) include a partial structure represented by the formula (3-1) (hereinafter, referred to also as “Q1 partial structure”), a partial structure represented by the formula (3-2) (hereinafter, referred to also as “Q2 partial structure”), a partial structure represented by the formula (3-3) (hereinafter, referred to also as “Q3 partial structure”) and a partial structure represented by the formula (3-4) (hereinafter, referred to also as “Q4 partial structure”).

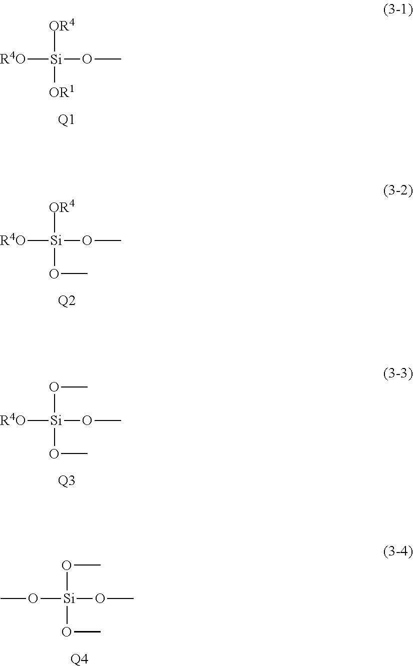

(wherein, R⁴ represents the same meaning as described above)

The alkoxysilane partial condensate having a partial structure represented by the formula (3) is preferably constituted of “Q1 partial structure”, “Q2 partial structure”, “Q3 partial structure” and “Q4 partial structure” at optional combination and ratio. The whole structure of the alkoxysilane partial condensate having a partial structure represented by the formula (3) may be any of straight chain, cycle, ladder, basket and random morphology.

When volatility of the alkoxysilane partial condensate having a partial structure represented by the formula (3) is low, control of the mixing ratio is easy in mixing the polysiloxane represented by the formula (1) and the alkoxysilane partial condensate having a partial structure represented by the formula (3), and a desired cured product is obtained easily in curing the composition of the present embodiment. From these standpoints, it is preferable that the alkoxysilane partial condensate having a partial structure represented by the formula (3) is a liquid material. The viscosity at 25° C. of the liquid material is usually 2 to 500 mPa·s, preferably 2 to 300 mPa·s, more preferably 2 to 100 mPa·s. When the lower limit of the viscosity of the liquid material is within these ranges, the volatility of the alkoxysilane partial condensate having a partial structure represented by the formula (3) tends to lower. When the upper limit of the viscosity of the liquid material is within these ranges, it becomes easy to mix with the polysiloxane represented by the formula (1) uniformly. The viscosity of the liquid material can be measured, for example, by a B-type rotational viscometer.

The alkoxysilane partial condensate having a partial structure represented by the formula (3) includes, for example, a condensate obtained by adding water to a hydrolyzable tetraalkoxysilane, then, condensing the silane via a dehydration reaction of an alkoxy group and a hydroxyl group and a dealcoholization reaction, by addition of a catalyst and/or heating.

The hydrolyzable tetraalkoxysilane includes, for example, tetramethoxysilane and tetraethoxysilane. Of them, tetramethoxysilane is preferable, from the standpoint of stability of the viscosity of the composition of the present embodiment and easiness of curing of the composition.

Specific examples of the Q-type alkoxysilane partial condensate having no hydroxyl group include Methyl Silicate 51, Methyl Silicate 53A, Ethyl Silicate 40 and Ethyl Silicate 48 manufactured by COLCOAT Co., Ltd. and Silicate 40, Silicate 45 and M Silicate 51 manufactured by Tama Chemicals Co., Ltd.

The amount of the alkoxysilane partial condensate having no hydroxyl group contained in the composition of the present embodiment is preferably 1 to 15 parts by weight, more preferably 2 to 7 parts by weight, when the amount of the polysiloxane represented by the formula (1) is 100 parts by weight.

### [Phosphoric Acid-Based Catalyst]

The phosphoric acid-based catalyst contained in the composition of the present embodiment includes, for example, compounds represented by the formula (4-1) or (4-2).

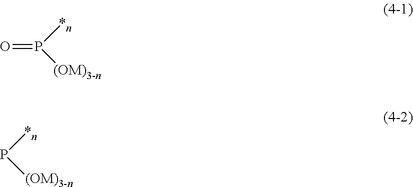

(wherein, n represents an integer of 0 to 2. M represents a counter cation. * represent an atom or atomic group other than (OM). When a plurality of M are present, they may be the same or different. When a plurality of * are present, they may be the same or different.)

The counter cation represented by M includes, for example, a hydrogen ion

The atom or atomic group represented by * includes, for example, OR and R (wherein R represents a monovalent organic group).

Specific examples of the phosphoric acid-based catalyst include inorganic phosphoric acids such as phosphoric acid, phosphorous acid and the like; phosphates such as monomethyl phosphate, dimethyl phosphate, trimethyl phosphate, monoethyl phosphate, diethyl phosphate, triethyl phosphate, monoisopropyl phosphate, diisopropyl phosphate, triisopropyl phosphate and the like; phosphites such as monomethyl phosphite, dimethyl phosphite, trimethyl phosphite, monoethyl phosphite, diethyl phosphite, triethyl phosphite, monoisopropyl phosphite, diisopropyl phosphite, triisopropyl phosphite and the like; and mixtures thereof. Of them, preferable is phosphoric acid, monomethyl phosphate, dimethyl phosphate, trimethyl phosphate, monoethyl phosphate, diethyl phosphate, triethyl phosphate, monomethyl phosphite, dimethyl phosphite, trimethyl phosphite, monoethyl phosphite, diethyl phosphite or triethyl phosphite.

In production of the composition of the present embodiment, a solution obtained by previously diluting a phosphoric acid-based catalyst with a solvent may be used. As the dilution solvent, general organic solvents; ketone solvents such as acetone, methyl ethyl ketone and the like; alcohol solvents such as methanol, ethanol, isopropyl alcohol, normal propyl alcohol and the like, and additionally, silicone oils such as liquid alkoxysilanes, dimethylsiloxane and the like; etc. can be used.

The amount of the phosphoric acid-based catalyst contained in the composition of the present embodiment is preferably 0.01 part by weight to 30 parts by weight, more preferably 0.1 part by weight to 20 parts by weight, when the total amount of the polysiloxane represented by the formula (1) and the alkoxysilane partial condensate having no hydroxyl group is 100 parts by weight.

### [Other Optional Components]

The composition of the present embodiment may comprise components other than the polysiloxane represented by the formula (1), the alkoxysilane partial condensate having no hydroxyl group and the phosphoric acid-based catalyst (hereinafter, referred to also as “other optional component”).

The other optional component includes, for example, an inorganic filler, an inorganic fluorescent substance, an anti-degradation agent, a radical inhibitor, an ultraviolet absorber, an adhesiveness improver, a flame retardant, a surfactant, a preservation stability improver, an antiozonant, a light stabilizer, a thickening agent, a plasticizer, a coupling agent, an antioxidant, a thermal stabilizer, a conductivity imparting agent, an antistatic agent, a radiation blocker, a nucleating agent, a phosphorus-based peroxide decomposing agent, a lubricant, a pigment, a metal deactivator, a physical property conditioner and an organic solvent. The composition of the present embodiment may comprise one other optional component singly or may comprise two or more other optional components.

It is preferable that the composition of the present embodiment comprises an inorganic filler as the other optional component, from the standpoint of controlling flowability of the composition, from the standpoint of controlling the refractive index of a cured product of the composition and from the standpoint of controlling the strength of a cured product of the composition. The inorganic filler is preferably a fine-grained filler from the standpoint of maintaining the light transmission of a cured product of the composition of the present embodiment, and examples thereof include zirconia, alumina, aluminum hydroxide, molten silica, crystalline silica, ultrafine amorphous silica, hydrophobic ultrafine silica, talc, calcium carbonate and barium sulfate.

### [Method of Producing Composition]

The composition of the present embodiment can be produced by mixing the polysiloxane represented by the formula (1), the alkoxysilane partial condensate having no hydroxyl group and the phosphoric acid-based catalyst, and if necessary, the other optional components, by a known method.

In one embodiment of the production method of the composition of the present embodiment, first, the polysiloxane represented by the formula (1) and the alkoxysilane partial condensate having no hydroxyl group are mixed, then, heated, to prepare a uniform mixture. It is preferable to remove impurities such as low molecular weight siloxanes and the like possibly present in the polysiloxane represented by the formula (1) and/or the alkoxysilane partial condensate having no hydroxyl group, in this preparation step. Next, the phosphoric acid-based catalyst is mixed with the mixture prepared.

When both the polysiloxane represented by the formula (1) and the alkoxysilane partial condensate having no hydroxyl group are liquid materials, a mixed liquid can be prepared by mixing them as they are. When one of the polysiloxane represented by the formula (1) and the alkoxysilane partial condensate having no hydroxyl group is a liquid material and the other is a solid, it is preferable that this solid is dissolvable in the liquid material in a heating step.

The temperature of the heating step is preferably 90 to 170° C., more preferably 110 to 150° C.

In another embodiment of the production method of the composition of the present embodiment, a solution comprising the polysiloxane represented by the formula (1), a solution comprising the alkoxysilane partial condensate having no hydroxyl group and a solution comprising the phosphoric acid-based catalyst are prepared separately, then, these solutions are mixed.

### [Semiconductor Light Emitting Device]

The composition of the present embodiment may comprise a solvent for facilitating potting onto a semiconductor light emitting element placed on a substrate, and the composition is preferably a solution dissolved in a solvent. The viscosity of the solution is preferably 10 to 10000 mPa·s.

The solvent includes, for example, ketone solvents such as acetone, methyl ethyl ketone and the like; alcohol solvents such as methanol, ethanol, isopropyl alcohol, normal propyl alcohol and the like; hydrocarbon solvents such as hexane, cyclohexane, heptane, benzene and the like; acetate solvents such as methyl acetate, ethyl acetate and the like; ether solvents such as tetrahydrofuran and the like; glycol ether solvents such as ethylene glycol monomethyl ether, ethylene glycol monoethyl ether, ethylene glycol monoisopropyl ether, ethylene glycol monobutyl ether, ethylene glycol monohexyl ether, ethylene glycol monoethylhexyl ether, ethylene glycol monophenyl ether, ethylene glycol monobenzyl ether, diethylene glycol monomethyl ether, diethylene glycol monoethyl ether, diethylene glycol monoisopropyl ether, diethylene glycol monobutyl ether, diethylene glycol monohexyl ether, diethylene glycol monoethyl hexyl ether, diethylene glycol monophenyl ether, diethylene glycol monobenzyl ether, propylene glycol monomethyl ether, propylene glycol monoethyl ether, propylene glycol monoisopropyl ether, propylene glycol monobutyl ether, propylene glycol monohexyl ether, propylene glycol monoethyl hexyl ether, propylene glycol monophenyl ether, propylene glycol monobenzyl ether, dipropylene glycol monomethyl ether, dipropylene glycol monoethyl ether, dipropylene glycol monoisopropyl ether, dipropylene glycol monobutyl ether, dipropylene glycol monohexyl ether, dipropylene glycol monoethyl hexyl ether, dipropylene glycol monophenyl ether, dipropylene glycol monobenzyl ether and the like; and glycol ester solvents such as ethylene glycol monoethyl ether acetate, ethylene glycol monoisopropyl ether acetate, ethylene glycol monobutyl ether acetate, ethylene glycol monohexyl ether acetate, ethylene glycol monoethyl hexyl ether acetate, ethylene glycol monophenyl ether acetate, ethylene glycol monobenzyl ether acetate and the like.

The semiconductor light emitting device of the present embodiment comprises a semiconductor light emitting element and an encapsulating layer comprising a cured product obtained by curing the composition of the present embodiment (hereinafter, referred to also as “cured product of the composition of the present embodiment”.

The semiconductor light emitting device of the present embodiment can be produced by a method comprising a first step of placing a semiconductor light emitting element on a substrate, a second step of potting the composition of the present embodiment on the semiconductor light emitting element and a third step of curing the potted composition of the present embodiment.

The first step of placing a semiconductor light emitting element on a substrate can be carried out by a known method. On the substrate, an electrode, wiring and the like may be placed. The semiconductor light emitting element is preferably a UV-LED device. The UV-LED device denotes an LED device which can emit ultraviolet light of 380 nm or less.

The second step of potting the composition of the present embodiment on the semiconductor light emitting element can be usually carried out by a method using a dispenser.

The third step of curing the potted composition of the present embodiment can be usually carried out by heating the composition of the present embodiment, to polycondense the composition of the present embodiment. The heating temperature is preferably 100 to 200° C., more preferably 120 to 200° C. The heating time is preferably 1 to 5 hours. The heating atmosphere is usually air under atmospheric pressure. The heating temperature may be raised in a stepwise fashion, from the standpoint of promoting volatilization of a solvent contained in the composition of the present embodiment and from the standpoint of promoting the polycondensation reaction of the composition of the present embodiment.

If the thickness of the cured product of the composition of the present embodiment is represented by t [mm] and the average transmission of the cured product at 220-320 nm is represented by T (t), it is preferable that T (1.3) is 80% or more. The reason for this is that when the semiconductor light emitting device of the present embodiment has a UV-LED device, light extraction efficiency increases and a semiconductor light emitting device showing high luminance is obtained under this condition.

The light transmission of the cured product of the composition of the present embodiment can be measured, for example, by a method described in examples.

### EXAMPLES

The embodiment of the present invention will be illustrated specifically by examples and comparative examples shown below, but the embodiment of the present invention is not limited to the following examples.

In the present example, conditions for measurement of ultraviolet visible transmission are as described below.

### <Measurement of Ultraviolet Visible Transmission>

Name of apparatus: UV-3600, manufactured by Shimadzu Corp.

Attachment: integrating sphere ISR-3100

Measurement wavelength: 220 to 800 nm

Background measurement: atmospheric air

Measurement speed: medium speed

In the present example, conditions for measurement of the viscosity of an alkoxysilane partial condensate having no hydroxyl group are as described below.

### <Measurement of Viscosity>

Name of apparatus: TVB-15M, manufactured by TOKI SANGYO Co., Ltd.

Measurement temperature: 25° C.

### Example 1

### (Production of Composition)

First, into a vessel equipped with a stirring machine, a thermometer and a nitrogen introduction tube were added 186 parts by weight of a silanol both-terminated polydimethylsiloxane (manufactured by Gelest, trade name: “DMS-S27”, standard polystyrene-equivalent weight-average molecular weight: 26400) and 14 parts by weight of a methyltrimethoxysilane partial condensate (manufactured by Shin-Etsu Chemical Co., Ltd., trade name: “KR-500”, viscosity: 27 mPa·s (25° C.)), and the liquid was heated at 120° C. After stirring at 120° C. for 3 hours, the liquid was stirred at 140° C. for 5 hours, to obtain a mixture (A).

Next, into another vessel were added 80 parts by weight of the mixture (A) and 120 parts by weight of a silanol both-terminated polydimethylsiloxane (manufactured by Gelest, trade name: “DMS-S42”, standard polystyrene-equivalent weight-average molecular weight: 90600) and the liquid was stirred at normal temperature, to obtain a mixture (B-1).

Regarding the mixing ratio in the mixture (B-1), the ratio of the methyltrimethoxysilane partial condensate was 3 parts by weight with respect to 100 parts by weight of the whole silanol both-terminated polydimethylsiloxane.

Next, into another vessel were added 100 parts by weight of the mixture (B-1) and 1 part by weight of a phosphoric acid-based catalyst (manufactured by Shin-Etsu Chemical Co., Ltd., trade name: “X-40-2309A”, phosphoric acid concentration: 15%) and the liquid was stirred at normal temperature, to obtain a composition (B-2).

### (Production of Cured Product)

The composition (B-2) was poured into a metal mold made of a polytetrafluoroethylene resin, and heated at 105° C. for 3 hours, then, heated at 150° C. for 5 hours, to fabricate a 1.3 mm thick cured product (B-3).

### Comparative Example 1

### (Production of Composition)

First, into a vessel equipped with a stirring machine, a thermometer and a nitrogen introduction tube were added 190 parts by weight of a silanol both-terminated polysiloxane (1) (manufactured by Momentive⋅Performance⋅Materials⋅Japan, trade name: “YF3800”) and 47 parts by weight of a tetraethoxysilane partial condensate (2) (manufactured by Tama Chemicals Co., Ltd., trade name: “Silicate 40”, viscosity: 5.1 mPa·s, average number n of Si atoms in the molecule=5) and the liquid was heated at 140° C. Thereafter, 0.05 parts by weight of dibutyltin dilaurate was added as a catalyst to this and the liquid was stirred at 140° C. for 6 hours, to obtain a mixture (C-1) as an alkoxysilane modified polysiloxane.

Next, into another vessel were added 100 parts by weight of the mixture (C-1) and 1.5 parts by weight of tin octylate and the liquid was stirred at normal temperature, to obtain a composition (C-2).

### (Production of Cured Product)

The composition (C-2) was poured into a metal mold made of a polytetrafluoroethylene resin, and heated at 105° C. for 3 hours, then, heated at 150° C. for 5 hours, to fabricate a 1.3 mm thick cured product (C-3).

### Example 2

### (Production of Composition)

First, into a 50 ml plastic vessel were added 7 parts by weight of a silanol both-terminated polydimethylsiloxane (manufactured by Gelest, trade name: “DMS-S32”, standard polystyrene-equivalent weight-average molecular weight: 57000), 0.105 parts by weight of a tetraethoxysilane partial condensate (manufactured by COLCOAT Co., Ltd., trade name: “Ethyl Silicate 48”, viscosity: 22.4 mPa·s (25° C.)) and 3.5 parts by weight of 2-butoxyethyl acetate (manufactured by KH Neochem Co., Ltd., trade name: “Butyl Acetate”), then, the vessel was attached to a rotating and revolving mixer (manufactured by THINKY, Awatori Neritarou ARV-310) and stirring was performed, to obtain a mixture (D-1).

Regarding the mixing ratio in the mixture (D-1), the ratio of the tetraethoxysilane partial condensate was 1.5 parts by weight with respect to 100 parts by weight of the whole silanol both-terminated polydimethylsiloxane.

Next, a mixture obtained by diluting a mixture of monomethyl phosphate and dimethyl phosphate (manufactured by Daihachi Chemical Industry Co., Ltd., trade name: “AP-1”) to 15% by weight with 2-butoxyethy acetate was added, as the phosphoric acid-based catalyst, in an amount of 0.07 parts by weight with respect to 100 parts by weight of the mixture (D-1), and the vessel was attached to a rotating and revolving mixer (manufactured by THINKY, Awatori Neritarou ARV-310) and stirring was performed, to obtain a composition (D-2).

### Example 3

### (Production of Composition)

First, into a 50 ml plastic vessel were added 7 parts by weight of a silanol both-terminated polydimethylsiloxane (manufactured by Gelest, trade name: “DMS-S32”, standard polystyrene-equivalent weight-average molecular weight: 57000), 0.21 parts by weight of a tetraethoxysilane partial condensate (manufactured by COLCOAT Co., Ltd., trade name: “Ethyl Silicate 48”, viscosity: 22.4 mPa·s (25° C.)) and 3.5 parts by weight of 2-butoxyethyl acetate (manufactured by KH Neochem Co., Ltd., trade name: “Butyl Acetate”), then, the vessel was attached to a rotating and revolving mixer (manufactured by THINKY, Awatori Neritarou ARV-310) and stirring was performed, to obtain a mixture (E-1).

Regarding the mixing ratio in the mixture (E-1), the ratio of the tetraethoxysilane partial condensate was 3.0 parts by weight with respect to 100 parts by weight of the whole silanol both-terminated polydimethylsiloxane.

Next, a mixture obtained by diluting a mixture of monomethyl phosphate and dimethyl phosphate (manufactured by Daihachi Chemical Industry Co., Ltd., trade name: “AP-1”) to 15% by weight with 2-butoxyethy acetate was added, as the phosphoric acid-based catalyst, in an amount of 0.07 parts by weight with respect to 100 parts by weight of the mixture (E-1), and the vessel was attached to a rotating and revolving mixer (manufactured by THINKY, Awatori Neritarou ARV-310) and stirring was performed, to obtain a composition (E-2).

### Example 4

### (Production of Composition)

First, into a 50 ml plastic vessel were added 7 parts by weight of a silanol both-terminated polydimethylsiloxane (manufactured by Gelest, trade name: “DMS-S32”, standard polystyrene-equivalent weight-average molecular weight: 57000), 0.35 parts by weight of a tetraethoxysilane partial condensate (manufactured by COLCOAT Co., Ltd., trade name: “Ethyl Silicate 48”, viscosity: 22.4 mPa·s (25° C.)) and 3.5 parts by weight of 2-butoxyethyl acetate (manufactured by KH Neochem Co., Ltd., trade name: “Butyl Acetate”), then, the vessel was attached to a rotating and revolving mixer (manufactured by THINKY, Awatori Neritarou ARV-310) and stirring was performed, to obtain a mixture (F-1).

Regarding the mixing ratio in the mixture (F-1), the ratio of the tetraethoxysilane partial condensate was 5.0 parts by weight with respect to 100 parts by weight of the whole silanol both-terminated polydimethylsiloxane.

Next, a mixture obtained by diluting a mixture of monomethyl phosphate and dimethyl phosphate (manufactured by Daihachi Chemical Industry Co., Ltd., trade name: “AP-1”) to 15% by weight with 2-butoxyethy acetate was added, as the phosphoric acid-based catalyst, in an amount of 0.07 parts by weight with respect to 100 parts by weight of the mixture (F-1), and the vessel was attached to a rotating and revolving mixer (manufactured by THINKY, Awatori Neritarou ARV-310) and stirring was performed, to obtain a composition (F-2).

### Example 5

### (Production of Composition)

First, into a 50 ml plastic vessel were added 7 parts by weight of a silanol both-terminated polydimethylsiloxane (manufactured by Gelest, trade name: “DMS-S32”, standard polystyrene-equivalent weight-average molecular weight: 57000), 0.49 parts by weight of a tetraethoxysilane partial condensate (manufactured by COLCOAT Co., Ltd., trade name: “Ethyl Silicate 48”, viscosity: 22.4 mPa·s (25° C.)) and 3.5 parts by weight of 2-butoxyethyl acetate (manufactured by KH Neochem Co., Ltd., trade name: “Butyl Acetate”), then, the vessel was attached to a rotating and revolving mixer (manufactured by THINKY, Awatori Neritarou ARV-310) and stirring was performed, to obtain a mixture (G-1).

Regarding the mixing ratio in the mixture (G-1), the ratio of the tetraethoxysilane partial condensate was 7.0 parts by weight with respect to 100 parts by weight of the whole silanol both-terminated polydimethylsiloxane.

Next, a mixture obtained by diluting a mixture of monomethyl phosphate and dimethyl phosphate (manufactured by Daihachi Chemical Industry Co., Ltd., trade name: “AP-1”) to 15% by weight with 2-butoxyethy acetate was added, as the phosphoric acid-based catalyst, in an amount of 0.07 parts by weight with respect to 100 parts by weight of the mixture (G-1), and the vessel was attached to a rotating and revolving mixer (manufactured by THINKY, Awatori Neritarou ARV-310) and stirring was performed, to obtain a composition (G-2).

### Example 6

### (Production of Composition)

First, into a 50 ml plastic vessel were added 7 parts by weight of a silanol both-terminated polydimethylsiloxane (manufactured by Gelest, trade name: “DMS-S32”, standard polystyrene-equivalent weight-average molecular weight: 57000), 0.70 parts by weight of a tetraethoxysilane partial condensate (manufactured by COLCOAT Co., Ltd., trade name: “Ethyl Silicate 48”, viscosity: 22.4 mPa·s (25° C.)) and 3.5 parts by weight of 2-butoxyethyl acetate (manufactured by KH Neochem Co., Ltd., trade name: “Butyl Acetate”), then, the vessel was attached to a rotating and revolving mixer (manufactured by THINKY, Awatori Neritarou ARV-310) and stirring was performed, to obtain a mixture (H-1).

Regarding the mixing ratio in the mixture (H-1), the ratio of the tetraethoxysilane partial condensate was 10.0 parts by weight with respect to 100 parts by weight of the whole silanol both-terminated polydimethylsiloxane.

Next, a mixture obtained by diluting a mixture of monomethyl phosphate and dimethyl phosphate (manufactured by Daihachi Chemical Industry Co., Ltd., trade name: “AP-1”) to 15% by weight with 2-butoxyethy acetate was added, as the phosphoric acid-based catalyst, in an amount of 0.07 parts by weight with respect to 100 parts by weight of the mixture (H-1), and the vessel was attached to a rotating and revolving mixer (manufactured by THINKY, Awatori Neritarou ARV-310) and stirring was performed, to obtain a composition (H-2).

### (Production of Cured Product)

Each of the compositions (D-2) to (H-2) produced in Examples 2 to 6 was poured into a metal mold made of a polytetrafluoroethylene resin, and heated at 150° C. for 10 hours, to fabricate 1.3 mm thick cured products (D-3) to (H-3).

### <Test 1>

### (Measurement of Ultraviolet Visible Transmission of Cured Product)

The transmission (light permeability) of each of the cured products (B-3) to (H-3) in the wavelength range from 220 nm to 320 nm was measured.

### <Test 2>

### (Evaluation of Heat Resistance of Cured Product)

Each of the cured products (B-3) to (H-3) was placed in an oven and heated at 250° C. for 60 hours, then, the ultraviolet visible transmission was measured, and the transmission (light permeability) in the wavelength range from 220 nm to 320 nm was measured.

### <Test 3>

### (Evaluation of Heat Resistance on LTCC Substrate)

Each of the compositions (B-2) to (H-2) was dropped onto the center of an LTCC substrate used for mounting of a semiconductor light emitting element, and heated at 105° C. for 3 hours, then, heated at 150° C. for 5 hours, to fabricate about 1 mm thick cured products (B-4) to (H-4). Each of the cured products (B-4) to (H-4) was placed in an oven, and heated at 250° C. for 60 hours, then, the cured product was observed, and no observation of cracks was judged as heat resistance: ∘ and observation of cracks was judged as heat resistance: x.

Test 1 (result of measurement of ultraviolet visible transmission of cured product), Test 2 (result of evaluation of heat resistance of cured product) and Test 3 (result of evaluation of heat resistance on LTCC substrate) measured above are shown in Table 1.

TABLE 1

| | | Comparative | | | | | |
|---|---|---|---|---|---|---|---|
| | Example 1 | Example 1 | Example 2 | Example 3 | Example 4 | Example 5 | Example 6 |
| | B-4 | C-4 | D-4 | E-4 | F-4 | G-4 | H-4 |
| Test 1 | 87% | 74% | 89% | 89% | 87% | 86% | 87% |
| Test 2 | 91% | 27% | 89% | 89% | 88% | 87% | 87% |
| Test 3 | ∘ | x | ∘ | ∘ | ∘ | ∘ | ∘ |

1. A composition comprising
a polysiloxane represented by the formula (1),
at least one alkoxysilane partial condensate having no hydroxyl group selected from the group consisting of a T-type alkoxysilane partial condensate having no hydroxyl group and a Q-type alkoxysilane partial condensate having no hydroxyl group, and
a phosphoric acid-based catalyst: 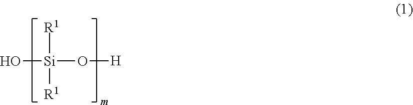
wherein
m represents an integer of 5 to 3000, and
R¹ represents an alkyl group, and the plurality of R¹ may be the same or different.

2. The composition according to claim 1, wherein the T-type alkoxysilane partial condensate having no hydroxyl group is an alkoxysilane partial condensate having a partial structure represented by the formula (2):
R²—Si(O—)ₙ(OR³)₃₋ₙ (2)
wherein
n represents an integer of 1 to 3,
R² represents an alkyl group, and
R³ represents a methyl group or an ethyl group, and when a plurality of R³ are present, they may be the same or different.

3. The composition according to claim 1, wherein the Q-type alkoxysilane partial condensate having no hydroxyl group is an alkoxysilane partial condensate having a partial structure represented by the formula (3):
Si(O—)ₘ(OR⁴)₄₋ₘ (3)
wherein
m represents an integer of 1 to 4, and
R⁴ represents a methyl group or an ethyl group, and when a plurality of R⁴ are present, they may be the same or different.

4. The composition according to claim 1, wherein the blending amount of the at least one alkoxysilane partial condensate having no hydroxyl group selected from the group consisting of the T-type alkoxysilane partial condensate having no hydroxyl group and the Q-type alkoxysilane partial condensate having no hydroxyl group is 1 to 15 parts by weight with respect to 100 parts by weight of the polysiloxane.

5. The composition according to claim 1, wherein the standard polystyrene-equivalent weight-average molecular weight of the polysiloxane represented by the formula (1) is 5000 to 200000.

6. A cured product obtained by curing the composition according to claim 1.

7. A semiconductor light emitting device comprising a semiconductor light emitting element and an encapsulating layer comprising the cured product according to claim 6.

8. The semiconductor light emitting device according to claim 7, wherein the semiconductor light emitting element is a UV-LED element.
